(19) United States
(12) Patent Application Publication
(10) Pub. No.: US 2022/0285928 A1
(43) Pub. Date: Sep. 8, 2022

(54) ELECTROSTATIC PROTECTION CIRCUITS AND FULL-CHIP ELECTROSTATIC PROTECTION CIRCUITS

(71) Applicant: QiAn Xu, (US)

(72) Inventor: QiAn Xu, (US)

(21) Appl. No.: 17/431,123

(22) PCT Filed: Mar. 8, 2021
(86) PCT No.: PCT/CN2021/079552

§ 371 Date: Aug. 13, 2021

(51) Int. Cl. H02H 1/00; H02H 3/22

(52) U.S. Cl. CPC H02H 1/0007; H02H 3/22

(57) ABSTRACT

The present application relates to an electrostatic protection circuit and a full-chip electrostatic protection circuit, wherein the electrostatic protection circuit comprises a detection module, a discharge module, and a control module. The detection module is configured to detect the type of a first voltage and output the detection result. The control module is configured to control the discharge module to be turned on or off based on the detection result of the detection module.

### CROSS-REFERENCE TO RELATED APPLICATIONS

The present application claims the priority to Chinese Patent Application No. 202010224007.7, entitled “ELECTROSTATIC PROTECTION CIRCUITS AND FULL-CHIP ELECTROSTATIC PROTECTION CIRCUITS”, filed to the State Intellectual Property Office of People's Republic of China on Mar. 26, 2020, which is incorporated herein by reference in its entirety.

### TECHNICAL FIELD

The present application relates to the technical field of integrated circuits, and in particular to an electrostatic protection circuit and a full-chip electrostatic protection circuit.

### BACKGROUND OF THE PRESENT INVENTION

Nowadays, semiconductor manufacturing processes are getting more advanced, semiconductor devices are getting smaller, the junction depth is getting lower, and the oxide layer is getting thinner. The reliability of semiconductor integrated circuits is facing more and more challenges. Especially, the electrostatic protection is becoming more important. According to statistics, more than about 30% of the failures of semiconductor products are caused by electrostatic damage. In order to better protect the integrated circuits from electrostatic damage, it is necessary to provide an electrostatic protection circuit to protect the integrated circuits.

The RC time constant of the existing electrostatic protection circuits is usually 0.1 μs to 1 μs. However, the existing electrostatic protection circuits need a large RC time constant in order to achieve better electrostatic protection effect. As a result, the electrostatic protection circuits have a large area and will occupy a large design space.

### SUMMARY OF THE PRESENT INVENTION

In a first aspect of the present application, an electrostatic protection circuit is provided, comprising:

a detection module, having a first terminal connected to a first voltage and a second terminal connected to a second voltage, configured to detect the type of the first voltage and output a detection result through a third terminal of the detection module;

a discharge module, having a first terminal connected to the first voltage and a second terminal connected to the second voltage; and

a control module, having a first terminal connected to the first voltage, a second terminal connected to the second voltage, a third terminal connected to the third terminal of the detection module, and a fourth terminal connected to the third end of the discharge module, configured to control the discharge module to be turned on or be turned off based on the detection result of the detection module.

This electrostatic protection circuit has a small RC time constant on the premise of achieving the required electrostatic protection effect, and the electrostatic protection circuit has a small area and will not occupy a large design space.

In a second aspect of the present application, a full-chip electrostatic protection circuit is further provided, comprising:

the electrostatic protection circuit according to the first aspect of the present application;

a core circuit, having a first terminal connected to the first voltage and a second terminal connected to the second voltage;

a first diode, having an anode connected to a signal input terminal of the core circuit and a cathode connected to the first voltage;

a second diode, having an anode connected to the second voltage and a cathode connected to the signal input terminal of the core circuit;

a third diode, having an anode connected to a signal output terminal of the core circuit and a cathode connected to the first voltage; and

a fourth diode, having an anode connected to the second voltage and a cathode connected to the signal output terminal of the core circuit.

This full-chip electrostatic protection circuit can realize electrostatic protection in four pressure modes by combining the diodes with the electrostatic protection circuit, which effectively improves the electrostatic protection capability of the product. It better ensures that the electrostatic protection device will not be turned on during the power-on and normal operation. The normal operation of the circuit is ensured without affecting the normal functioning of the existing core circuit.

### BRIEF DESCRIPTION OF THE DRAWINGS

In order to better describe and illustrate the embodiments of the present application, reference may be made to one or more drawings. However, the additional details or examples used to describe the drawings should not be considered as any limitation to the concept of the present application or any one of the currently described embodiments or preferred implementations.

FIG. 1 is a circuit diagram of an electrostatic protection circuit according to an embodiment;

FIG. 2a is a circuit diagram of an electrostatic protection circuit according to another embodiment;

FIG. 2b is a circuit diagram of an electrostatic protection circuit according to another embodiment;

FIG. 3 is a circuit diagram of a full-chip electrostatic protection circuit according to an embodiment; and

FIG. 4 is a circuit diagram of a full-chip electrostatic protection circuit according to another embodiment.

### DETAILED DESCRIPTION OF THE PRESENT INVENTION

In order to facilitate the understanding of the present application, the present application will be described more fully below with reference to the relevant drawings. Preferred embodiments of the present application are shown in the drawings. However, the present application may be implemented in many different forms and is not limited to the embodiments described herein. On the contrary, these embodiments are provided to make the disclosure of the present application more thorough and comprehensive.

It should be noted that, when an element is referred to as being “connected to” other elements, the element may be connected to the other elements directly or with intervening elements therebetween. The terms “installed”, “one terminal”, “the other terminal” and similar expressions used herein are for illustrative purposes only.

Unless otherwise defined, all technical and scientific terms used herein have the same meaning as commonly understood by a person of ordinary skill in the art to which the present application belongs. Here, terms used in the description of the present application are merely intended to describe specific embodiments, rather than limiting the present application. As used herein, the term “and/or” includes any or all of one or more associated items listed here or combinations thereof.

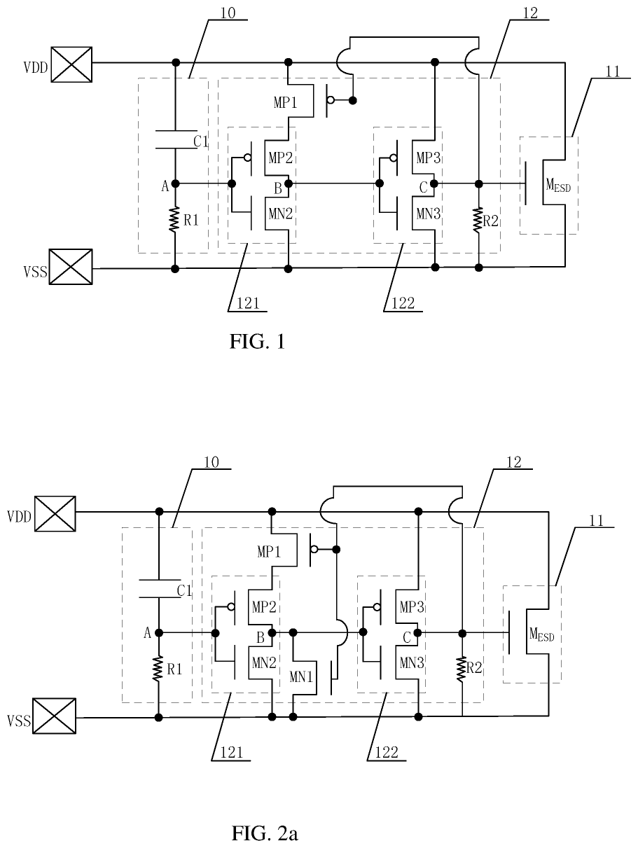

In an embodiment, as shown in FIG. 1, an electrostatic protection circuit of the present application comprises: a detection module 10, having a first terminal connected to a first voltage VDD and a second terminal connected to a second voltage VSS, configured to detect the type of the first voltage VDD and output the detection result through a third terminal (terminal A in FIG. 1) of the detection module 10; a discharge module 11, having a first terminal connected to the first voltage VDD and a second terminal connected to the second voltage VSS; and a control module 12, having a first terminal connected to the first voltage VDD, a second terminal connected to the second voltage VSS, a third terminal connected to the third terminal of the detection module 10, and a fourth terminal (terminal C in FIG. 1) connected to a third terminal of the discharge module 11, configured to control the discharge module 11 to be turned on or off based on the detection result of the detection module 10.

This electrostatic protection circuit has a small RC time constant on the premise of achieving the required electrostatic protection effect, and the electrostatic protection circuit has a small area and will not occupy a large design space.

In an example, the detection module 10 comprises: a capacitor C1, having a first terminal connected, as the first terminal of the detection module 10, to the first voltage VDD and a second terminal used as the third terminal of the detection module 10; and a resistor R1, having a first terminal connected to the second terminal of the capacitor C1 and a second terminal used as the second terminal of the detection module 10.

Specifically, the capacitor C1 may comprise, but is not limited to, a metal-dielectric-metal capacitor or an MOS capacitor; and the resistor R1 may comprise, but is not limited to, a polyresistor or a doped region resistor.

In an example, the discharge module 11 may comprise a discharge transistor MESD. The discharge transistor MESD may be an NMOS transistor. A drain of the discharge transistor MESD is connected, as the first terminal of the discharge module 11, to the first voltage VDD; a source of the discharge transistor MESD is connected, as the second terminal of the discharge module 11, to the second voltage VSS; and a gate of the discharge transistor MESD is connected, as the third terminal of the discharge module 11, to the fourth terminal of the control module 12.

In an example, the control module 12 comprises a positive feedback loop. The positive feedback loop comprises an inverter and a PMOS transistor.

In an example, the control module 12 comprises: a first inverter 121, having a first terminal connected, as the third terminal of the control module 12, to the third terminal of the detection module 10, and a second terminal connected to the second voltage VSS; a second inverter 122, having a first terminal connected to a fourth terminal of the first inverter 121, a second terminal connected to the second voltage VSS, and a third terminal connected to the first voltage VDD; a first PMOS transistor MP1, having a gate connected to a fourth terminal of the second inverter 122, a source connected to the first voltage VDD, and a drain connected to the third terminal of the first inverter 121; wherein, the first PMOS transistor MP1 and the second inverter 122 form the positive feedback loop.

In an example, the first inverter 121 comprises a second PMOS transistor MP2 and a second NMOS transistor MN2; the gate of the second PMOS transistor MP2 and the gate of the second NMOS transistor MN2 are connected together as the third terminal of the control module 12, the source of the second PMOS transistor MP2 is connected to the drain of the first PMOS transistor MP1, and the drain of the second PMOS transistor MP2 and the drain of the second NMOS transistor MN2 are connected together as the fourth terminal (terminal B in FIG. 1) of the first inverter 121; the source of the second NMOS transistor MN2 is used as the second terminal of the first inverter 121.

In an example, the second inverter 122 comprises a third PMOS transistor MP3 and a third NMOS transistor MN3; the gate of the third PMOS transistor MP3 and the gate of the third NMOS transistor MN3 are connected together as the first terminal of the second inverter 122, the source of the third PMOS transistor MP3 is used as the third terminal of the second inverter 122, the source of the third PMOS transistor MP3 and the source of the first PMOS transistor MP1 are connected, as the first terminal of the control module 12, to the first voltage VDD, the drain of the third PMOS transistor MP3 and the drain of the third NMOS transistor MN3 are connected together as the fourth terminal of the second inverter 122, and the source of the third NMOS transistor MN3 is used as the second terminal of the second inverter 122.

In an example, the electrostatic protection circuit further comprises a pull-down resistor R2, a first terminal of the pull-down resistor R2 and the fourth terminal of the second inverter 122 are connected together as the fourth terminal of the control module 12, a second terminal of the pull-down resistor R2 is connected to the second voltage VSS, and the second terminal of the pull-down resistor R2, the second terminal of the first inverter 121 and the second terminal of the second inverter 122 together form the second terminal of the control module 12.

Specifically, the resistance R2 may comprise, but is not limited to, a polyresistor or a doped region resistor.

The working principle of the electrostatic protection circuit shown in FIG. 1 will be described below. When electrostatic current occurs, the third terminal (terminal A in FIG. 1) of the detection module 10 is coupled to a high level through the capacitor C1 and the second NMOS transistor MN2 is turned on, and after the electrostatic current flows through the second NMOS transistor MN2, the fourth terminal (terminal B in FIG. 1) of the first inverter 121 is at a low level, the third PMOS transistor MP3 is turned on, the voltage at the fourth terminal (terminal C in FIG. 1) of the control module 12 increases, and the discharge transistor MESD is turned on to discharge the electrostatic current; the increase of the voltage at the fourth terminal of the control module 12 will weaken the conduction of the first PMOS transistor, which in turn further decreases the voltage at the fourth terminal of the first inverter 121 and further increases the gate voltage of the discharge transistor MESD. Such a positive feedback method can accelerate the electrostatic discharge. After a certain period of time, when the voltage at the third terminal of the detection module 10 becomes low due to the discharge by the resistor R1, the second NMOS transistor MN2 is turned off and the second PMOS transistor MP2 is turned on. However, because the fourth terminal of the control module 12 is still at a high level, the first PMOS transistor MP1 is turned off and the third NMOS transistor MN3 is turned on. Therefore, the feedback through the first PMOS transistor MP1 and the third NMOS transistor MN3 can ensure that the fourth terminal of the first inverter 121 is still at a low level, so as to ensure that the fourth terminal of the control module 12 remains at a high level. In this way, the electrostatic discharge time becomes longer, thereby ensuring the conduction speed of the discharge transistor MESD and the electrostatic discharge capacity. Thus, the RC time constant of the electrostatic protection circuit can be reduced. The reduced RC time constant can in turn lead to the reduced size of the electrostatic protection circuit, so that the design space occupied by the electrostatic protection circuit becomes smaller.

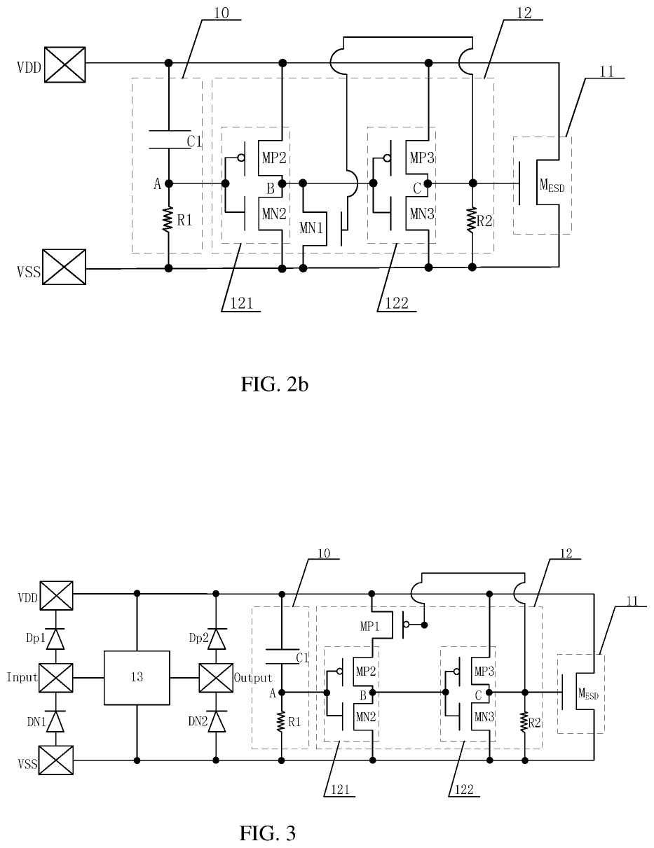

In another example, the positive feedback loop comprises an inverter, a PMOS transistor, and an NMOS transistor. Specifically, as shown in FIG. 2a, compared with the electrostatic protection circuit in FIG. 1, the electrostatic protection circuit in this example further comprises a first NMOS transistor MN1 on the basis of the electrostatic protection circuit in FIG. 1. The gate of the first NMOS transistor MN1 is connected to the fourth terminal of the second inverter 122. Specifically, the gate of the first NMOS transistor MN1 is connected to the drain of the third PMOS transistor MP3 and the drain of the third NMOS transistor MN3, the drain of the first NMOS transistor MN1 is connected to the fourth terminal of the first inverter 121, the source of the first NMOS transistor MN1 is connected to the second voltage VSS, and the source of the first NMOS transistor MN1, the source of the second NMOS transistor MN2 and the source of the third NMOS transistor MN3 are used together as the second terminal of the control module 12. The first PMOS transistor MP1, the first NMOS transistor MN1 and the second inverter 122 form a positive feedback loop.

The working principle of the electrostatic protection circuit shown in FIG. 2a will be described below. When electrostatic current occurs, the third terminal (terminal A in FIG. 2a) of the detection module 10 is coupled to a high level through the capacitor C1 and the second NMOS transistor MN2 is turned on, and after the electrostatic current flows through the second NMOS transistor MN2, the fourth terminal (terminal B in FIG. 2a) of the first inverter 121 is at a low level, the third PMOS transistor MP3 is turned on, the voltage at the fourth terminal (terminal C in FIG. 2a) of the control module 12 is at a high level, and the discharge transistor MESD is turned on to discharge the electrostatic current; the increase of the voltage at the fourth terminal of the control module 12 will weaken the conduction of the first PMOS transistor and meanwhile the first NMOS transistor MN1 is turned on, which can further accelerate the pull-down of the potential at the fourth terminal of the first inverter 121, so that the voltage at the fourth terminal of the first inverter 121 decreases faster and the gate voltage of the discharge transistor MESD is further increased. Such a positive feedback method can accelerate the electrostatic discharge. After a certain period of time, when the voltage at the third terminal of the detection module 10 becomes low due to the discharge by the resistor R1, the second NMOS transistor MN2 is turned off and the second PMOS transistor MP2 is turned on. However, because the fourth terminal of the control module 12 is still at a high level, the first PMOS transistor MP1 is turned off, the first NMOS transistor MN1 is turned on, and the first NMOS transistor MN1 is turned on to pull the level of the fourth terminal of the first inverter 121 down, so that the level of the fourth terminal of the first inverter 121 is further decreased. Therefore, the feedback through the first PMOS transistor MP1, the third NMOS transistor MN3 and the first NMOS transistor MN1 can ensure that the fourth terminal of the first inverter 121 is still at a low level, so as to ensure that the fourth terminal of the control module 12 remains at a high level. Thus, the electrostatic discharge time becomes longer than that of the electrostatic protection circuit shown in FIG. 1. Further, by setting an appropriate size for MN3, for example increasing the channel width of the first NMOS transistor MN1, the fourth terminal of the first inverter 121 can always maintain at a low level during the electrostatic discharge process until the electrostatic charges are all discharged. Therefore, the conduction speed of the discharge transistor MESD and the electrostatic discharge capacity are ensured. Thus, the RC time constant of the electrostatic protection circuit can be reduced. The reduced RC time constant can in turn lead to the reduced size of the electrostatic protection circuit, so that the design space occupied by the electrostatic protection circuit becomes smaller.

Of course, in other examples, the positive feedback loop comprises an inverter and an NMOS transistor. Specifically, as shown in FIG. 2b, the electrostatic protection circuit in this example may not comprise the first PMOS transistor MP1, when compared with that in FIG. 2a. The other circuit structures in this example are the same as the corresponding structures in FIG. 2a, and will not be repeated here. In this example, the first NMOS transistor MN1 and the second inverter 122 form a positive feedback loop.

The working principle of the electrostatic protection circuit shown in FIG. 2b will be described below. When electrostatic current occurs, the third terminal (terminal A in FIG. 2b) of the detection module 10 is coupled to a high level through the capacitor C1 and the second NMOS transistor MN2 is turned on, and after the electrostatic current flows through the second NMOS transistor MN2, the fourth terminal (terminal B in FIG. 2b) of the first inverter 121 is at a low level, the third PMOS transistor MP3 is turned on, the voltage at the fourth terminal (terminal C in FIG. 2b) of the control module 12 is at a high level, and the discharge transistor MESD is turned on to discharge the electrostatic current; the increase of the voltage at the fourth terminal of the control module 12 will cause the first NMOS MN1 transistor to be turned on, which can accelerate the pull-down of the potential at the fourth terminal of the first inverter 121, so that the voltage at the fourth terminal of the first inverter 121 decreases faster and the gate voltage of the discharge transistor MESD is further increased. Such a positive feedback method can accelerate the electrostatic discharge. After a certain period of time, when the voltage at the third terminal of the detection module 10 becomes low due to the discharge by the resistor R1, the second NMOS transistor MN2 is turned off and the second PMOS transistor MP2 is turned on. However, because the fourth terminal of the control module 12 is still at a high level, the first NMOS transistor MN1 is turned on. The turning-on of the first NMOS transistor MN1 can pull the level of the fourth terminal of the first inverter 121 down, so that the level of the fourth terminal of the first inverter 121 further decreases. Therefore, the feedback through the third NMOS transistor MN3 and the first NMOS transistor MN1 can ensure that the fourth terminal of the first inverter 121 is still at a low level, so as to ensure that the fourth terminal of the control module 12 remains at a high level, thereby ensuring the conduction speed of the discharge transistor MESD and the electrostatic discharge capacity. Thus, the RC time constant of the electrostatic protection circuit can be reduced. The reduced RC time constant can in turn lead to the reduced size of the electrostatic protection circuit, so that the design space occupied by the electrostatic protection circuit becomes smaller.

Referring to FIG. 3, the present application further provides a full-chip electrostatic protection circuit, comprising: the electrostatic protection circuit as shown in FIG. 1; a core circuit 13, having a first terminal connected to the first voltage VDD and a second terminal connected to the second voltage VSS, wherein the core circuit 13 may be any existing circuit that needs electrostatic protection and its specific structure will not be repeated here; a first diode Dp1, having an anode connected to a signal input terminal (terminal Input in FIG. 3) of the core circuit 13 and a cathode connected to the first voltage VDD; a second diode DN1, having an anode connected to the second voltage VSS and a cathode connected to the signal input terminal of the core circuit 13; a third diode Dp2, having an anode connected to a signal output terminal (terminal Output in FIG. 3) of the core circuit 13 and a cathode connected to the first voltage VDD; and a fourth diode DN2, having an anode connected to the second voltage VSS and a cathode connected to the signal output terminal of the core circuit 13.

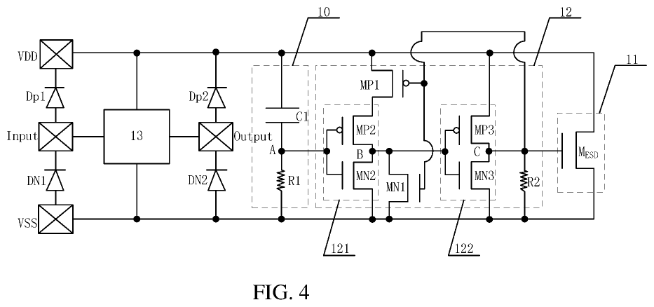

Referring to FIG. 4, the present application further provides a full-chip electrostatic protection circuit, comprising: the electrostatic protection circuit as shown in FIG. 2a; a core circuit 13, having a first terminal connected to the first voltage VDD and a second terminal connected to the second voltage VSS, wherein the core circuit 13 may be any existing circuit that needs electrostatic protection and its specific structure will not be repeated here; a first diode Dp1, having an anode connected to a signal input terminal (terminal Input in FIG. 3) of the core circuit 13 and a cathode connected to the first voltage VDD; a second diode DN1, having an anode connected to the second voltage VSS and a cathode connected to the signal input terminal of the core circuit 13; a third diode Dp2, having an anode connected to a signal output terminal (terminal Output in FIG. 3) of the core circuit 13 and a cathode connected to the first voltage VDD; and a fourth diode DN2, having an anode connected to the second voltage VSS and a cathode connected to the signal output terminal of the core circuit 13.

Of course, in other embodiments, the present application further provides a full-chip electrostatic protection circuit. The full-chip electrostatic protection circuit in this embodiment is substantially the same as the full-chip electrostatic protection circuit shown in FIG. 4, with the only difference that the electrostatic protection circuit in the full-chip electrostatic protection circuit shown in FIG. 4 is the electrostatic protection circuit shown in FIG. 2a, and the electrostatic protection circuit in the full-chip protection circuit in this embodiment is the electrostatic protection circuit shown in FIG. 2b.

The full-chip electrostatic protection circuit shown in FIG. 3 and FIG. 4 provides electrostatic protection in four pressure modes: PD mode, ND mode, NS mode and PS mode. In the PD mode, the full-chip electrostatic protection circuit discharges electrostatic current through the first diode Dp1 or the third diode Dp2; in the ND mode, the full-chip electrostatic protection circuit discharges electrostatic current through the second diode DN1, the fourth diode DN2, and the discharge transistor MESD; in the NS mode, the full-chip electrostatic protection circuit discharges the electrostatic current through the second diode DN1 and the fourth diode DN2; and in the PS mode, the full-chip electrostatic protection circuit discharges the electrostatic current through the first diode Dp1 or the third diode Dp2 and the discharge transistor MESD.

Various technical features of the above embodiments may be arbitrarily combined. For simplicity, all possible combinations of various technical features of the above embodiments are not described. However, all those technical features shall be included in the protection scope of the present invention if not conflict.

The embodiments described above merely represent certain implementations of the present application. Although those embodiments are described in more specific details, it is not to be construed as any limitation to the scope of the present application. It should be noted that, for a person of ordinary skill in the art, a number of variations and improvements may be made without departing from the concept of the present application, and those variations and improvements should be regarded as falling into the protection scope of the present application. Therefore, the protection scope of the present application should be subject to the appended claims.

1. An electrostatic protection circuit, comprising:
a detection module having a first terminal connected to a first voltage and a second terminal connected to a second voltage, the detection module configured to detect a type of the first voltage and output a detection result through a third terminal of the detection module;
a discharge module having a first terminal connected to the first voltage and a second terminal connected to the second voltage; and
a control module having a first terminal connected to the first voltage, a second terminal connected to the second voltage, a third terminal connected to the third terminal of the detection module, and a fourth terminal connected to the third terminal of the discharge module, the control module configured to control the discharge module to be turned on or be turned off based on the detection result of the detection module.

2. The electrostatic protection circuit according to claim 1, wherein the detection module comprises:
a capacitor having a first terminal used as the first terminal of the detection module and a second terminal used as the third terminal of the detection module; and
a resistor having a first terminal connected to the second terminal of the capacitor and a second terminal used as the second terminal of the detection module.

3. The electrostatic protection circuit according to claim 2, wherein the capacitor comprises a metal-dielectric-metal capacitor or a metal oxide semiconductor (MOS) capacitor, and the resistor comprises a polyresistor or a doped region resistor.

4. The electrostatic protection circuit according to claim 1, wherein the discharge module comprises a discharge transistor.

5. The electrostatic protection circuit according to claim 4, wherein the discharge transistor comprises an N-type metal oxide semiconductor (NMOS) transistor, a drain of the discharge transistor is used as the first terminal of the discharge module, and a source of the discharge transistor is used as the second terminal of the discharge module, and a gate of the discharge transistor is used as the third terminal of the discharge module.

6. The electrostatic protection circuit according to claim 1, wherein the control module comprises a positive feedback loop, the positive feedback loop comprises an inverter and an NMOS transistor, or the positive feedback loop comprises an inverter and a P-type metal oxide semiconductor (PMOS) transistor, or the positive feedback loop comprises an inverter, a PMOS transistor, and an NMOS transistor.

7. The electrostatic protection circuit according to claim 6, wherein the control module comprises:
a first inverter having a first terminal used as the third terminal of the control module and a second terminal connected to the second voltage;
a second inverter having a first terminal connected to a fourth terminal of the first inverter, a second terminal connected to the second voltage, and a third terminal connected to the first voltage; and
a first PMOS transistor having a gate connected to a fourth terminal of the second inverter, a source connected to the first voltage and used, together with the third terminal of the second inverter, as the first terminal of the control module, and a drain connected to a third terminal of the first inverter; wherein,
the first PMOS transistor and the second inverter form the positive feedback loop.

8. The electrostatic protection circuit according to claim 6, wherein the control module comprises:
a first inverter having a first terminal used as the third terminal of the control module and a second terminal connected to the second voltage; and
a second inverter having a first terminal connected to a fourth terminal of the first inverter, a second terminal connected to the second voltage, and a third terminal connected to the first voltage; wherein,
a gate of a first NMOS transistor is connected to a fourth terminal of the second inverter, a drain of the first NMOS transistor is connected to the fourth terminal of the first inverter, and a source of the first NMOS transistor is connected to the second voltage; and
the first NMOS transistor and the second inverter form the positive feedback loop.

9. The electrostatic protection circuit according to claim 6, wherein the control module comprises:
a first inverter having a first terminal used as the third terminal of the control module and a second terminal connected to the second voltage;
a second inverter having a first terminal connected to a fourth terminal of the first inverter, a second terminal connected to the second voltage, and a third terminal connected to the first voltage; and
a first PMOS transistor having a gate connected to a fourth terminal of the second inverter, a source connected to the first voltage and used, together with the third terminal of the second inverter, as the first terminal of the control module, and a drain connected to a third terminal of the first inverter; wherein,
a gate of a first NMOS transistor is connected to the fourth terminal of the second inverter, a drain of the first NMOS transistor is connected to the fourth terminal of the first inverter, and a source of the first NMOS transistor is connected to the second voltage; and
the first PMOS transistor, the first NMOS transistor and the second inverter form the positive feedback loop.

10. The electrostatic protection circuit according to claim 7, wherein,
the first inverter comprises a second PMOS transistor and a second NMOS transistor; a gate of the second PMOS transistor and a gate of the second NMOS transistor are connected together as the third terminal of the control module, a source of the second PMOS transistor is connected to the drain of the first PMOS transistor, and a drain of the second PMOS transistor and a drain of the second NMOS transistor are connected together as the fourth terminal of the first inverter; a source of the second NMOS transistor is used as the second terminal of the first inverter; and
the second inverter comprises a third PMOS transistor and a third NMOS transistor; a gate of the third PMOS transistor and a gate of the third NMOS transistor are connected together as the first terminal of the second inverter, a source of the third PMOS transistor is used as the third terminal of the second inverter, the source of the third PMOS transistor and the source of the first PMOS transistor are used together as the first terminal of the control module, a drain of the third PMOS transistor and a drain of the third NMOS transistor are connected together as the fourth terminal of the second inverter, and a source of the third NMOS transistor is used as the second terminal of the second inverter.

11. The electrostatic protection circuit according to claim 10, wherein the electrostatic protection circuit further comprises a pull-down resistor, a first terminal of the pull-down resistor and the fourth terminal of the second inverter are used as the fourth terminal of the control module, a second terminal of the pull-down resistor is connected to the second voltage, and the second terminal of the pull-down resistor, the second terminal of the first inverter and the second terminal of the second inverter together form the second terminal of the control module.

12. A full-chip electrostatic protection circuit, comprising:
the electrostatic protection circuit according to claim 1;
a core circuit having a first terminal connected to the first voltage and a second terminal connected to the second voltage;
a first diode having an anode connected to a signal input terminal of the core circuit and a cathode connected to the first voltage;
a second diode having an anode connected to the second voltage and a cathode connected to the signal input terminal of the core circuit;
a third diode having an anode connected to a signal output terminal of the core circuit and a cathode connected to the first voltage; and
a fourth diode having an anode connected to the second voltage and a cathode connected to the signal output terminal of the core circuit.

13. The electrostatic protection circuit according to claim 9, wherein,
the first inverter comprises a second PMOS transistor and a second NMOS transistor; a gate of the second PMOS transistor and a gate of the second NMOS transistor are connected together as the third terminal of the control module, a source of the second PMOS transistor is connected to the drain of the first PMOS transistor, and a drain of the second PMOS transistor and a drain of the second NMOS transistor are connected together as the fourth terminal of the first inverter; a source of the second NMOS transistor is used as the second terminal of the first inverter; and
the second inverter comprises a third PMOS transistor and a third NMOS transistor; a gate of the third PMOS transistor and a gate of the third NMOS transistor are connected together as the first terminal of the second inverter, a source of the third PMOS transistor is used as the third terminal of the second inverter, the source of the third PMOS transistor and the source of the first PMOS transistor are used together as the first terminal of the control module, a drain of the third PMOS transistor and a drain of the third NMOS transistor are connected together as the fourth terminal of the second inverter, and a source of the third NMOS transistor is used as the second terminal of the second inverter.

14. The full-chip electrostatic protection circuit according to claim 12, wherein the detection module comprises:
a capacitor having a first terminal used as the first terminal of the detection module and a second terminal used as the third terminal of the detection module; and
a resistor having a first terminal connected to the second terminal of the capacitor and a second terminal used as the second terminal of the detection module.

15. The full-chip electrostatic protection circuit according to claim 14, wherein the capacitor comprises a metal-dielectric-metal capacitor or a MOS capacitor, and the resistor comprises a polyresistor or a doped region resistor.

16. The full-chip electrostatic protection circuit according to claim 12, wherein the discharge module comprises a discharge transistor.

17. The full-chip electrostatic protection circuit according to claim 16, wherein the discharge transistor comprises an NMOS transistor, a drain of the discharge transistor is used as the first terminal of the discharge module, and a source of the discharge transistor is used as the second terminal of the discharge module, and a gate of the discharge transistor is used as the third terminal of the discharge module.

18. The full-chip electrostatic protection circuit according to claim 12, wherein the control module comprises a positive feedback loop, the positive feedback loop comprises an inverter and an NMOS transistor, or the positive feedback loop comprises an inverter and a PMOS transistor, or the positive feedback loop comprises an inverter, a PMOS transistor, and an NMOS transistor.
